(19) United States
(12) Patent Application Publication
(10) Pub. No.: US 2003/0068841 A1
(43) Pub. Date: Apr. 10, 2003

(54) Process of producing semiconductor device and resin composition sheet used therefor

(75) Inventors: Akiko Matsumura, Ibaraki-shi (JP); Sadahito Misumi, Ibaraki-shi (JP); Yuji Hotta, Ibaraki-shi (JP)

Correspondence Address: SUGHRUE MION, PLLC, 2100 PENNSYLVANIA AVENUE, N.W., WASHINGTON, DC, 20037, US

(73) Assignee: NITTO DENKO CORPORATION

(21) Appl. No.: 10/253,426

(22) Filed: Sep. 25, 2002

(30) Foreign Application Priority Data
Sep. 26, 2001 (JP) P2001-294348

(51) Int. Cl. H01L 51/40; H01L 21/44; H01L 21/30

(52) U.S. Cl. 438/113; 438/458; 438/459

(57) ABSTRACT

A process of producing a semiconductor device comprises the steps of:

adhering a resin composition of sheet form comprising a polycarbodiimide copolymer to the active side of a silicon wafer,

back-grinding the silicon wafer while being supported by the resin composition,

dicing the silicon wafer into semiconductor chips, and

sealing the gap between the semiconductor chip and a substrate with said resin composition adhered to the semiconductor chip; and

an adhesive resin composition of sheet form for a silicon wafer comprises a polycarbodiimide copolymer represented by formula (I).

### FIELD OF THE INVENTION

This invention relates to a process of producing a semiconductor device wherein a sheet of a resin composition is used for back grinding as well as for underfilling. The present invention also relates to a resin composition of sheet form which is suited for back grinding as well as for underfilling in the production of a semiconductor device.

### BACKGROUND OF THE INVENTION

With the recent tendency to high-density assembly of semiconductor devices, flip chip technology using bumped ICs has been spreading rapidly. Further, to meet the demand for reducing the thickness of semiconductor devices, back grinding of a silicon wafer for thickness reduction has been introduced. In particular, the latest spread of chip scale packages (CSPs) has boosted the demand for further reducing the thickness of bumped wafers. In order to obtain such a thin bumped wafer as demanded, wafer bumping is preceded by back grinding of a wafer to a desired thickness.

However, because a back-ground thin wafer is difficult to transport and also because wafers have recently been gaining in diameter, it has been keenly demanded to establish a technique enabling back grinding after bumping.

A process including sticking a back grinding tape onto the active side of a bumped wafer and then grinding the back side of the bumped wafer is known as a solution of the above subject. However, with such a back grinding tape, it has been difficult to achieve high efficiency in producing bumped and back-ground wafers on account of insufficient conformability of the tape to the unevenness formed by bumps and a wafer surface. That is, water can penetrate between the tape and the active side of the wafer during back grinding, unevenness ascribed to the bumps may be reflected on the ground wafer surface, or the thin wafer can warp and crack. Besides, the resulting wafers cannot be seen as sufficiently satisfactory for the market demands.

The back-ground wafer is diced into bumped semiconductor chips. Each chip is mounted on a substrate, and the gap between the chip and the substrate is filled with a liquid thermosetting resin called an underfill material, which is then cured (underfilling). The underfilling process, which is indispensable for assuring electrical connections between a semiconductor chip and a substrate, involves a number of processing step. A simpler technique for achieving underfilling through a decreased number of steps has been demanded in the market.

### SUMMARY OF THE INVENTION

An object of the present invention is to provide a resin composition of sheet form which is capable of not only securely supporting a silicon wafer during back grinding but also serving as an underfill material in mounting a semiconductor chip on a substrate.

Another object of the invention is to provide a process of producing a semiconductor device by using the resin composition of sheet form.

The present invention provides a process of producing a semiconductor device which comprises the steps of:

adhering a resin composition of sheet form comprising a polycarbodiimide copolymer to the active side of a silicon wafer,

back-grinding the silicon wafer while being supported by the resin composition,

dicing the silicon wafer into semiconductor chips, and

sealing the gap between the semiconductor chip and a substrate with the resin composition adhered to the semiconductor chip.

The invention also provides an adhesive resin composition of sheet form which is suited to carry out the process of the invention, the composition comprising a polycarbodiimide copolymer represented by formula (I):

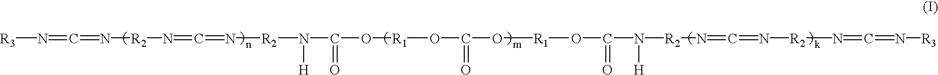

wherein R₁ represents an alkylene group having 2 to 10 carbon atoms; R₂ represents an aromatic diisocyanate residue; R₃ represents an aromatic monoisocyanate residue; k represents an integer of 0 to 30; m represents an integer of 2 to 100; and n represents an integer of 0 to 30.

The invention further provides a semiconductor device produced by the process of the invention.

According to the present invention, the sheet used in back grinding does not need to be removed from the wafer and can be used as an underfill material as such. The term “sheet” as used herein is used to inclusively denote the forms generally referred to as a sheet or a film.

### BRIEF DESCRIPTION OF THE DRAWING

FIG. 1 is a schematic view illustrating a silicon wafer fixed on a grinding stage.

### DESCRIPTION OF THE REFERENCE NUMERALS AND SIGNS

1: silicon wafer

2: sheet of resin composition

3: releasable plastic film

4: grinding stage

5: bump

### DETAILED DESCRIPTION OF THE INVENTION

The polycarbodiimide copolymer represented by formula (I) which can be used in the present invention is preferably produced by reacting a polycarbonate diol represented by formula (II):

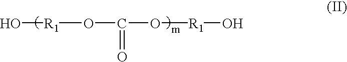

wherein R₁ represents an alkylene group having 2 to 10 carbon atoms; and m represents an integer of 2 to 100, with an aromatic diisocyanate to prepare a polyurethane, carbodiimidating the terminal isocyanate group of the polyurethane with the aromatic diisocyanate in the presence of a catalyst for carbodiimidation, and blocking the terminal with an aromatic monoisocyanate.

The aromatic diisocyanate is used in an amount of at least 2 mol, preferably 4 to 80 mol, still preferably 5 to 50 mol, per mol of the polycarbonate diol of formula (II). The reaction between the polycarbonate diol (II) and the aromatic diisocyanate is carried out in a solvent at a temperature usually from 0 to 120° C., preferably from 20 to 100° C., for a period of about 1 minute to 5 hours. The time when almost all the hydroxyl groups disappear is taken as the end point of the reaction for forming a polyurethane terminated with NCO at both ends thereof.

The polyurethane is allowed to react with the excess of the aromatic diisocyanate remaining in the reaction system in the presence of a carbodiimidation catalyst usually at 40 to 150° C., preferably 50 to 140° C., to obtain the copolymer of formula (I).

The amount of the aromatic diisocyanate required for carbodiimidation is at least 2 mol per mol of the polycarbonate. A requisite amount of the aromatic diisocyanate may be added in this stage or be present from the start of the polyurethane formation reaction. The terminal blocking with an aromatic monoisocyanate is preferably effected by adding the aromatic monoisocyanate in the initial, middle or final stage of the carbodiimidation or over the whole stage of the carbodiimidation.

The end point of the reaction is confirmed by observing the absorption assigned to a carbodiimido group at 2140 cm⁻¹ and disappearance of the absorption assigned to an isocyanate group at 2280 cm⁻¹ in IR spectrophotometry.

In formula (II) representing the polycarbonate diol, the alkylene group containing 2 to 10 carbon atoms as represented by R₁ includes ethylene, tetramethylene, hexamethylene, and octamethylene. m is an integer of 2 to 100, preferably 5 to 80.

The polycarbonate diol is not particularly limited as long as it is a polycarbonate diol containing a carbonate group. Useful polycarbonate diols include polyethylene carbonate diol, polytetramethylene carbonate diol, polyhexamethylene carbonate diol, polyoctamethylene carbonate diol, and polydodecamethylene carbonate diol, with polyhexamethylene carbonate diol being preferred. These polycarbonate diols can be used either individually or as a mixture of two or more thereof.

In formula (I), the aromatic diisocyanate residue as represented by R₂ includes a tolylene diisocyanate residue and a diphenylmethane diisocyanate residue; k is an integer of 0 to 30, preferably 2 to 20; and n is an integer of 0 to 30, preferably 2 to 20.

Accordingly, examples of the aromatic diisocyanate include 4,4′-diphenylmethane diisocyanate, 2,6-tolylene diisocyanate, 2,4-tolylene diisocyanate, 1-methoxyphenyl-2,4-diisocyanate, 3,3′-dimethoxy-4,4′-diphenylmethane diisocyanate, 4,4′-diphenyl ether diisocyanate, 3,3′-dimethyl-4,4′-diphenyl ether diisocyanate, 2,2-bis[4-(4-isocyanatophenoxy)phenyl]hexafluoropropane, and 2,2-bis[4-(4-isocyanatophenoxy)phenyl]propane, with tolylene diisocyanate being preferred. These diisocyanates can be used either individually or as a mixture of two or more thereof.

In carrying out the terminal blocking, it is desirable to add an aromatic monoisocyanate containing an R₃ group in the molecule thereof in the initial, middle or final stage of the polymerization reaction or over the whole stage of the polymerization. Examples of useful aromatic monoisocyanates are phenyl isocyanate, p-nitrophenyl isocyanate, p- or m-tolyl isocyanate, p-formylphenyl isocyanate, and p-isopropylphenyl isocyanate, with p-isopropylphenyl isocyanate being preferred. The thus terminal-blocked polycarbodiimide copolymer solution exhibits excellent storage stability.

The polymerization is preferably conducted at 40 to 150° C., particularly 50 to 140° C. At temperatures below 40° C. the reaction time would be too long for practical application. Reaction temperatures exceeding 150° C. will limit the range of usable solvents.

The diisocyanate monomer concentration in the reaction system ranges from 5 to 80% by weight (hereinafter simply represented by “%”). In concentrations lower than 5%, carbodiimidation can fail to proceed. Concentrations more than 80% can render reaction control difficult.

Conventionally known organic solvents are employable as a reaction solvent for carbodiimidation and as a solvent of a polycarbodiimide solution. Examples of useful organic solvents include halogenated hydrocarbons, such as tetrachloroethylene, 1,2-dichloroethane, and chloroform; ketones, such as acetone, methyl ethyl ketone, methyl isobutyl ketone, and cyclohexanone; cyclic ethers, such as tetrahydrofuran and dioxane; and aromatic hydrocarbons, such as toluene and xylene. These solvents can be used either alone or as a combination of two or more thereof.

The catalyst for carbodiimidation includes any kind of known phosphorus-based catalysts, such as phospholene oxides, e.g., 1-phenyl-2-phospholene-1-oxide, 3-methyl-2-phospholene-1-oxide, 1-ethyl-2-phospholene-1-oxide, 3-methyl-1-phenyl-2-phospholene-1-oxide, and 3-phospholene isomers of these oxides.

After completion of the copolymerization, unreacted monomers or the catalyst may be removed by pouring the reaction mixture into a poor solvent, such as methanol, ethanol, isopropyl alcohol or hexane, to precipitate the polycarbodiimide copolymer, which is separated from the system.

The precipitated polymer is washed and dried by appropriate operations and again dissolved in the above-recited organic solvent to prepare a polycarbodiimide solution with improved solution stability.

By-products present in the polymer solution may be removed by adsorption onto an appropriate adsorbent, such as alumina gel, silica gel, activated carbon, zeolite, active magnesia, activated bauxite, fuller's earth, activated clay, molecular sieve carbon, or a mixture thereof.

The polycarbodiimide copolymer of the invention has an average degree of polymerization of 2 to 160, preferably 9 to 120. Polycarbodiimide copolymers having a higher polymerization degree than 160 easily gelatinize in several minutes to several hours when allowed to stand at ambient temperature, which is unfavorable for practical use. Polycarbodiimide copolymers having a lower polymerization degree than 2 lack film reliability.

The sheet of the resin composition comprising the polycarbodiimide copolymer is prepared by forming a polycarbodiimide copolymer varnish into film with an appropriate thickness by known methods, such as casting, spin coating, and roll coating. The film is usually dried at a temperature that is necessary for solvent removal but not so high as to cause curing reaction to proceed considerably. That is, the drying temperature is, for example, 20 to 350° C., preferably 50 to 250° C., still preferably 70 to 200° C. At drying temperatures below 20° C., the solvent can remain in the resulting sheet, which reduces the reliability of the sheet. At drying temperatures above 350° C., thermal curing of the sheet can proceed.

If desired, the resin composition which is to be formed into sheeting may contain a fine inorganic filler within a range that does not ruin the processability and the heat resistance of the composition. Further, the resin composition may contain various additives such as smoothing agents, leveling agents, and defoaming agents to impart surface smoothness to the resulting sheet. These additives, such as inorganic fillers, are each added in an amount of 0.1 to 100 parts, preferably 0.2 to 50 parts, by weight per 100 parts by weight of the copolymer.

The resin composition can further contain various additives for improving adhesion, such as silane coupling agents, titanium coupling agents, nonionic surface active agents, fluorine surface active agents, and silicone additives.

For the purpose of imparting to the sheet electrical conductivity, improved thermal conductivity, controlled elastic modulus, and the like, the resin composition can additionally contain one or more of various inorganic powders, such as metals or alloys, e.g., aluminum, copper, silver, gold, nickel, chromium, lead, tin, zinc, palladium, and solder; ceramics, e.g., alumina, silica, magnesia, and silicon nitride; and carbon.

The resin composition may be formed into a sheet on a support to make a laminate adhesive sheet. Such a laminate adhesive sheet is produced by coating a support with a varnish of the polycarbodiimide copolymer or laminating a support with a previously prepared sheet of the polycarbodiimide copolymer composition by pressing or a like means.

The support which can be used in the laminate sheet includes metal foils and insulating films. The metal foils include aluminum, copper, silver, gold, nickel, indium, chromium, lead, tin, zinc, and palladium, and alloys of these metals. The insulating films can be of any heat-resistant and chemical-resistant materials, such as polyimide, polyester, and polyethylene terephthalate.

The metal foils and the insulating films may be used either individually or as a composite thereof. A composite support includes dual layer supports composed of a metal foil and an insulating film, such as a copper/polyimide dual layer support.

When the resin composition of sheet form is stuck onto a bumped wafer, it is required to conform to the uneven shape of the bumps formed on the wafer so as to prevent water from penetrating between the sheet and the wafer during back grinding. For this, it is preferred that the sheet be capable of plastic deformation at a temperature for sticking the sheet onto a bumped wafer. In this connection, the viscosity of the sheet preferably ranges from 10 to 10¹⁰ Pa·s, particularly 100 to 10⁹ Pa·s, at a temperature for sticking (20 to 150° C.).

The sheet preferably has a thickness of 5 to 250 μm, particularly 10 to 120 μm. It is especially preferred for the sheet to have a thickness of (average bump height+0 to 50 μm) Sheet thickness variations from the mean is preferably within ±5 μm.

The sheet is adhered to a silicon wafer at 20 to 150° C. In order to protect the sheet surface to be brought into contact with a wafer from contamination with dust, etc. and also to add strength for facilitating film transportation, it is advisable to provide a releasable plastic film for protection on the surface of the sheet.

The releasable plastic films include films of plastics, such as polyethylene terephthalate, polyester, polyvinyl chloride, polycarbonate or polyimide, having been treated with known release agents of silicone type, long-chain alkyl type, fluorine type, aliphatic amide type, silica type, etc. A fluoroplastic film (e.g., polytetrafluoroethylene), a polypropylene film, and a polyethylene film are also useful.

A laminate release film composed of the above-described plastic film and an adhesive layer capable of foaming on heating, an ultraviolet-curing adhesive layer or a like layer is also useful as a releasable plastic film fit for the objects of the present invention. The adhesive layer, which is in contact with the resin composition sheet, changes its adhesion on heating or ultraviolet irradiation to exhibit releasability.

Various methods can be adopted to protect the resin composition sheet with the releasable plastic film. For example, the sheet is sandwiched in between a pair of releasable plastic films, and the sandwich is pressed or rolled. The thus obtained resin composition of sheet form has a function of supporting a wafer during back grinding combined with a function as an underfill material in flip chip attach. By use of the resin composition sheet of the invention, water is prevented from penetrating during back grinding, and local differences in pressure applied to the back side of the wafer during back grinding, which are caused by the bumps formed on the opposite side of the wafer, are absorbed by the elasticity and plastic deformation of the sheet. As a result, a bumped wafer with a smooth ground surface can be obtained. Semiconductor chips diced out of the bumped and back-ground wafer can be mounted directly on a substrate via the resin composition sheet that has served as a support in back grinding. Thus, the present invention has achieved great simplification of steps involved for the production of semiconductor devices using bumped and back-ground chips.

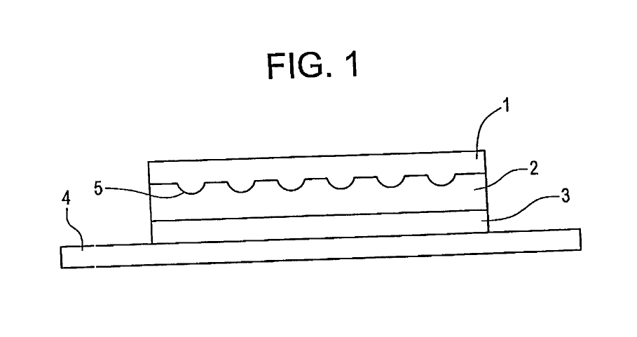

The process of producing a semiconductor device according to the present invention includes the steps of adhering the above-described resin composition of sheet form to a silicon wafer, back grinding the silicon wafer as supported on the resin composition, and sealing the gap between a semiconductor chip and a substrate with the resin composition.

Where a resin composition sheet protected with a releasable plastic film on both sides thereof is used, one of the releasable plastic films is peeled off, and a silicon wafer 1 is directly adhered onto the exposed surface of the sheet 2 as shown in FIG. 1. The laminate is fixed on a grinding stage 4 on the opposite releasable plastic film 3 side, and the back side of the silicon wafer 1 is ground. The back-ground silicon wafer 1 with the resin composition sheet 2 adhered thereto is diced into semiconductor chips. The releasable plastic film 3 is peeled from each chip, and the chip is flip chip bonded on a substrate with the resin composition sheet 2 side down by means of a flip chip bonder. The resulting component is then sealed by curing the resin composition by, for example, heating the component at 100 to 255° C., preferably 120 to 200° C., for 3 to 300 minutes, preferably 5 to 180 minutes.

The silicon wafer with the resin composition can be diced from either side. Where it is diced from the back side, the resin composition of sheet form functions as an underneath pad.

The above-described process in which back grinding is followed by dicing will be referred to as process A. The order of back grinding and dicing may be reversed to “dicing before grinding”. A “dicing before grinding” process will be referred to as process B. Process B is carried out as follows. A dicing tape is stuck to the back side of a bumped wafer. A dicing saw partially cuts the streets to make grooves on the active side of the wafer (half cut). The resin composition of sheet form according to the invention (with a releasable plastic film on one side thereof) is then adhered to the half-cut active side. The dicing tape is peeled off the back side, and a grinder grinds the exposed back side until it reaches the groove depth. The resin composition sheet is diced along the streets from the back side of the wafer, whereupon the wafer separates into individual semiconductor chips (with an underfill material adhered thereto) while being supported on the same releasable plastic film. Each chip with an underfill material adhered thereto is picked up from the releasable film and placed on a substrate with the underfill material side down. The device is then heat treated to achieve electrical connections between the chip and the substrate and to cure the resin composition to seal the interface between the chip and the substrate.

The semiconductor devices to which the present invention is applicable preferably include, but are not limited to, thin and fragile devices such as GaAs devices. In particular, where applied to the “dicing before grinding” technology, the present invention will realize a large-volume production process with superior stability.

The silicon wafer used in the present invention is not particularly limited. The silicon wafer does not always need to be bumped previously. While not limiting, the bump 5 preferably has a thickness of 2 to 200 μm.

Any known grinder having a grinding stage, e.g., DFG-840, supplied by Disco Corp., can be used for back grinding. Grinding conditions are not particularly limited.

The back-ground silicon wafer preferably has a thickness of about 50 to 600 μm. The dicing process and the size of the semiconductor chip are not particularly limited.

The semiconductor chip with the underfill material is mounted on a substrate with a commonly used flip chip bonder. Mounting conditions are not particularly limited within such ranges as to provide satisfactory electrical connections between the bumps and the substrate and are selected appropriately according to the materials of bumps and electrodes of the substrate. Curing of the underfill material and bump reflow can be carried out with the flip chip bonder or separate furnaces exclusively designed for underfilling or reflow.

The resulting semiconductor device has a smooth surface on the polished wafer and highly reliable electrical connections.

The present invention will now be illustrated in greater detail with reference to Examples and Comparative Examples. All the operations for producing polycarbodiimide were performed in a nitrogen stream. The characteristics of resulting polycarbodiimide were measured as follows.

1) IR spectrum

Measured with FT/IR-230, supplied by JEOL Ltd.

2) Number average molecular weight (Mn)

Measured by gel-permeation chromatography with a chromatograph HLC8120, available from Tosoh Corp., using columns GMH_{HR-H}, GMH_{HR-H}, and G2000H_{HR}, all available from Tosoh Corp., and tetrahydrofuran as a developing solvent.

3) Glass transition temperature (Tg)

Measured with a dynamic thermomechanical analyzer DMS 210, supplied by Seiko Instruments, Inc.

4) Tensile modulus (E′)

Measured with DMS 210.

5) Thermal decomposition initiation temperature (Td)

Measured with a thermogravimetric and differential thermal analyzer TG/DTA 300, supplied from Seiko Instruments, Inc. A 5% weight loss temperature was taken as a Td.

### PREPARATION EXAMPLE 1

Into a 500 ml four-necked flask equipped with a stirrer, a dropping funnel, a reflux condenser, and a thermometer were charged 100 g (0.57 mol) of tolylene diisocyanate (Takenate 80, available from Takeda Chemical Industries, Ltd.), 100 g (0.034 mol) of polyhexamethylene carbonate diol (UH-CARB300, available from Ube Industries, Ltd.), 112.5 g of xylene, and 37.5 g of cyclohexanone. The mixture was allowed to react at 100° C. for 3 hours for urethanation. After the reaction mixture was cooled to room temperature, 0.883 g (4.59 mmol) of 3-methyl-1-phenyl-2-phospholene-1-oxide as a carbodiimidation catalyst and 6.4793 g (40.2 mmol) of p-isopropylphenyl isocyanate were added thereto, and the mixture was stirred at 100° C. for 1 hour to conduct polymerization. IR spectrophotometry gave confirmation of carbodiimidation. The resulting polycarbodiimide had an Mn of 5400.

The resulting varnish was applied to a 105 μm thick copper foil and dried at 90° C. for 30 minutes and then at 200° C. for 30 minutes to obtain a resin sheet having an adhesive layer thickness of 30 μm. As a result of thermal characteristics analysis, the sheet was found to have a Tg of 120° C., a tensile modulus E′ of 17 MPa at 35° C., and a thermal decomposition initiation temperature Td of 395° C.

### PREPARATION EXAMPLE 2

Into a 500 ml four-necked flask equipped with a stirrer, a dropping funnel, a reflux condenser, and a thermometer were charged 100 g (0.57 mol) of tolylene diisocyanate (Takenate 80), 75 g of xylene, and 25 g of cyclohexanone. To the mixture were added 0.883 g (4.59 mmol) of 3-methyl-1-phenyl-2-phospholene-1-oxide as a carbodiimidation catalyst and 6.4793 g (40.2 mmol) of p-isopropylphenyl isocyanate, and the mixture was stirred at 100° C. for 1 hour to conduct polymerization. Carbodiimidation was confirmed from the IR spectrum. The resulting polycarbodiimide had an Mn of 4800.

The resulting varnish was applied to a 105 μm thick copper foil and dried at 90° C. for 30 minutes and then at 200° C. for 30 minutes to obtain a resin sheet with an adhesive layer thickness of 30 μm. As a result of thermal characteristics analysis, the sheet was found to have a Tg of 125° C., a tensile modulus E′ of 3400 MPa at 35° C., and a thermal decomposition initiation temperature Td of 400° C.

### EXAMPLE 1

### Process A

The varnish prepared in Preparation Example 1 was applied to a separator (a 50 μm thick release agent-treated polyethylene terephthalate (PETP) film) with coating equipment and dried at 150° C. to obtain a resin sheet having a thickness of 30 μm and single-side protected with the PETP film, which was taken up in roll form. Semiconductor devices were fabricated by using the resulting resin sheet according to process A as follows.

The exposed side of the resulting sheet was adhered to a bumped side of a silicon wafer of 6 in. in diameter and 625 μm in thickness and with 2 μm high gold bumps plated (91 peripheral bumps per chip at a pitch of 200 μm). The silicon wafer with the sheet was set on a grinding stage of a grinder DFG-840, available from Disco, Corp., with the wafer back side up, and the back side of the wafer was ground under prescribed grinding conditions (rough grinding was carried out with an abrasive grain size of #360 at a speed of 4800 rpm to reduce the wafer thickness to 320 μm, and final grinding was carried out with an abrasive grain size of #2000 at a speed of 6500 rpm to reduce the wafer thickness to 300 μm) to obtain a 300 μm thick bumped silicon wafer. The bumped silicon wafer with the resin sheet was diced with a dicer DAD522, supplied by Disco, into 8-mm square chips. The PETP film was removed from the resin sheet, and each of the chips was mounted on a substrate via the exposed resin sheet. The substrate used was an FPC dual layer substrate having a thickness of 45 μm, a height of trace of 20 μm, and an L/S of 100 μm/100 μm. The component was heat treated under conditions of a stage temperature of 150° C., a tool temperature of 250° C., a bonding load of 1.96 MPa/chip, and a bonding time of 60 seconds to melt the bumps thereby achieving electrical connections between the bumps and the substrate electrodes. The component was then heat treated at 125° C. for 30 minutes to cure the resin sheet to complete a semiconductor device.

In the above-described fabrication, the active side of the bumped silicon wafer after back grinding was inspected to find no invasion of water. The ground surface of the silicon wafer was found smooth as measured with a profilometer Surfcom.

Ten out of the resulting semiconductor devices were inspected for initial connection failure at 25° C. by use of a resistometer Digital Multimeter TR6847, supplied by Advantest Corp. A device whose resistance showed infinity (connection failure) was counted as a reject. Five out of the semiconductor devices which had passed initial connection test were subjected to a thermal cycling test at −25° C. (30 min) followed by room temperature (3 min) followed by 125° C. (30 min) per cycle. After 1000 full cycles were executed, electrical connection was again inspected by measuring the resistivity with the tester at room temperature. Further, other five out of the semiconductor devices which had passed initial connection test were subjected to a high temperature high humidity test at 85° C. and 85% RH for 500 hours, and electrical connection was inspected at room temperature (25° C.) with Digital Multimeter TR6847. After the thermal cycling test and the high temperature high humidity test, devices which showed a two- or more-fold increase in resistance over the initial value were counted as rejects. The results obtained are shown in Table 1 below.

### EXAMPLE 2

### Process B

The varnish prepared in Preparation Example 1 was applied to a separator (a 50 μm thick release agent-treated PETP film) with coating equipment and dried at 150° C. to obtain a resin sheet having a thickness of 30 μm and single-side protected with the PETP film, which was taken up in roll form. Semiconductor devices were fabricated by using the resulting resin sheet according to process B as follows.

An adhesive dicing tape Elep Holder V12S, available from Nitto Denko Corp., was adhered to the back side (non-bumped side) of a silicon wafer of 6 in. in diameter and 625 μm in thickness and with 2 μm high gold bumps plated (91 peripheral bumps per chip at a pitch of 200 μm). The silicon wafer was half cut on its bumped side to a depth of 350 μm to make 8-mm squares with a dicer DAD522, supplied by Disco. The resin sheet was then adhered to the bumped and half-cut side of the wafer. The dicing tape was peeled off the back side of the wafer, the wafer with the sheet was set on a grinding stage of a grinder DFG-840, available from Disco, with the wafer back side up, and the back side of the wafer was ground under prescribed grinding conditions (rough grinding was carried out with an abrasive grain size of #360 at a speed of 4800 rpm to reduce the wafer thickness to 320 μm, and final grinding was carried out with an abrasive grain size of #2000 at a speed of 6500 rpm to reduce the wafer thickness to 300 μm). The resin sheet was cut by dicing from the back ground side of the wafer to obtain 300 μm thick, 8-mm square semiconductor chips. Each chip with the resin sheet was picked up from the PETP film, mounted on the same substrate as used in Example 1 via the exposed resin sheet, and heat treated under conditions of a stage temperature of 150° C., a tool temperature of 250° C., a bonding load of 1.96 MPa/chip, and a bonding time of 60 seconds to melt the bumps thereby achieving electrical connections between the bumps and the substrate electrodes. The component was then heat treated at 125° C. for 30 minutes to cure the resin sheet to complete a semiconductor device.

In the above-described fabrication, the active side of the bumped silicon wafer after back grinding was inspected to find no invasion of water. The ground surface of the silicon wafer was found smooth as measured with a profilometer Surfcom. The resulting semiconductor devices were evaluated in the same manner as in Example 1. The results obtained are shown in Table 1.

### COMPARATIVE EXAMPLE 1

### Process A

The varnish prepared in Preparation Example 2 was applied to a separator (a 50 μm thick release agent-treated PETP film) with coating equipment and dried at 150° C. to obtain a resin sheet having a thickness of 30 μm and single-side protected with the PETP film, which was taken up in roll form. Semiconductor devices were fabricated and evaluated in the same manner as in Example 1, except for using the resulting resin sheet. The results of evaluation are shown in Table 1.

In the device fabrication, the active side of the bumped silicon wafer after back grinding was inspected to find no invasion of water. The ground surface of the silicon wafer was found smooth as measured with a profilometer Surfcom.

### COMPARATIVE EXAMPLE 2

### Process B

The varnish prepared in Preparation Example 2 was applied to a separator (a 50 μm thick release agent-treated PETP film) with coating equipment and dried at 150° C. to obtain a resin sheet having a thickness of 30 μm and single side protected with a PETP film, which was taken up in roll form. Semiconductor devices were fabricated and evaluated in the same manner as in Example 2, except for using the resulting resin sheet. The results of evaluation are shown in Table 1.

In the device fabrication, the active side of the bumped silicon wafer after back grinding was inspected to find no invasion of water. The ground surface of the silicon wafer was found smooth as measured with a profilometer Surfcom.

TABLE 1

| | Example | | Compara. Example | |
|---|---|---|---|---|
| | 1 | 2 | 1 | 2 |
| Initial Connection | 0/10 | 0/10 | 0/10 | 0/10 |
| Failure | | | | |
| Connection Failure | | | | |
| after Thermal | 0/5 | 0/5 | 4/5 | 3/5 |
| Cycle Test | | | | |
| Connection Failure | 0/5 | 0/5 | 4/5 | 4/5 |
| after High Temp. | | | | |
| High Humidity Test | | | | |

As can be seen from the results in Table 1, all the semiconductor devices of Examples were satisfactory in electrical connection reliability either in the initial stage and after the thermal cycle test and the high temperature high humidity test, proving highly reliable as compared with Comparative Examples. It is apparent that the semiconductor devices according to the present invention secure stable and high reliability in connection reliability tests such as thermal cycle test and high temperature high humidity test.

The resin composition of sheet form according to the present invention is capable of supporting a silicon wafer when back grinding and also performs the function as an underfill material when mounting a semiconductor chip on a substrate. Use of the resin composition of sheet form according to the invention enables wafer back grinding to give a smooth surface without allowing water to invade the active side of the wafer and also simplifies the chip mount assembly, thereby to fabricate semiconductor devices efficiently.

While the invention has been described in detail and with reference to specific embodiments thereof, it will be apparent to one skilled in the art that various changes and modifications can be made therein without departing from the spirit and scope thereof.

What is claimed is:

1. A process of producing a semiconductor device which comprises the steps of:
adhering a resin composition of sheet form comprising a polycarbodiimide copolymer to the active side of a silicon wafer,
back-grinding the silicon wafer while being supported by the resin composition,
dicing the silicon wafer into semiconductor chips, and
sealing the gap between the semiconductor chip and a substrate with said resin composition adhered to the semiconductor chip.

2. An adhesive resin composition of sheet form for a silicon wafer which comprises a polycarbodiimide copolymer represented by formula (I): 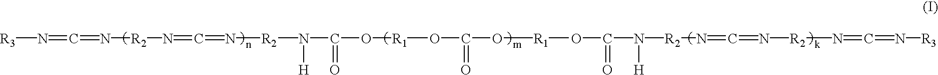
wherein R₁ represents an alkylene group having 2 to 10 carbon atoms; R₂ represents an aromatic diisocyanate residue; R₃ represents an aromatic monoisocyanate residue; k represents an integer of 0 to 30; m represents an integer of 2 to 100; and n represents an integer of 0 to 30.

3. The adhesive resin composition of sheet form according to claim 2, wherein R₁ is a hexamethylene group, and R₂ is a tolylene diisocyanate residue or a diphenylmethane diisocyanate residue.

4. The adhesive resin composition of sheet form according to claim 2, wherein R₃ is a p-isopropylphenyl isocyanate residue.

5. The adhesive resin composition of sheet form according to claim 2, which is protected with a releasable plastic film.

6. The adhesive resin composition of sheet form according to claim 3, which is protected with a releasable plastic film.

7. The adhesive resin composition of sheet form according to claim 4, which is protected with a releasable plastic film.
